(19) United States
(12) Patent Application Publication
(10) Pub. No.: US 2015/0187831 A1
(43) Pub. Date: Jul. 2, 2015

(54) SOLID STATE IMAGING DEVICE

(71) Applicant: KABUSHIKI KAISHA TOSHIBA, Tokyo (JP)

(72) Inventors: Hideki OSAMURA, Oita Oita (JP); Seiichi IWASA, Oita Oita (JP)

(21) Appl. No.: 14/474,026

(22) Filed: Aug. 29, 2014

(30) Foreign Application Priority Data
Dec. 26, 2013 (JP) 2013-269433

(51) Int. Cl. H01L 27/146

(52) U.S. Cl. CPC H01L 27/14645; H01L 27/14621; H01L 27/14627; H01L 27/1463; H01L 27/14636; H01L 27/14685

(57) ABSTRACT

According to one embodiment, a solid state imaging device includes a semiconductor substrate, a photodiode formed in the semiconductor substrate, a first insulating film having a first refractive index, and disposed on a surface of the semiconductor substrate, a second insulating film having a second refractive index higher than the first refractive index, and formed on the first insulating film above the photodiode, a third insulating film having a third refractive index higher than the second refractive index, and formed on the second insulating film above the photodiode, and a micro lens provided above the photodiode.

### CROSS-REFERENCE TO RELATED APPLICATION

This application is based upon and claims the benefit of priority from Japanese Patent Application No. 2013-269433, filed Dec. 26, 2013, the entire contents of which are incorporated herein by reference.

### FIELD

Embodiments described herein relate generally to a solid state imaging device.

### BACKGROUND

A solid state imaging device such as a CMOS image sensor has been used for digital electronic devices such as a digital camera because it requires only a low power supply voltage and has low power consumption. Digital electronic devices require a high light sensitivity in the imaging sensors to be incorporated into these electronic devices. A CMOS image sensor is provided with a plurality of pixels for converting light into an electric signal, and then it amplifies and transfers the electrical signal. More light can be absorbed as the area of each pixel is made larger or the alternatively the number of the pixels is increased, and as a result, the image sensor has a higher sensitivity. However, when an image sensor is miniaturized by reducing the area of each pixel, the area for absorbing light becomes smaller for each pixel and sensitivity per pixel becomes lower. Therefore, it is desirable for each pixel to have a high sensitivity.

In a CMOS image sensor, a photodiode (hereinafter, referred to as PD), which is a photoelectric conversion unit, is formed within or on a semiconductor substrate. A flattened (planarized) insulating film, a color filter, and a micro lens are sequentially formed on the semiconductor substrate and the PD. A wiring layer is formed within the insulating film. An insulating film with a refractive index higher than that of the flattened insulating film is formed within the wiring layer (that is, between wires in the layer). By coupling the insulating film with a high refractive index with the insulating film with a low refractive index, an optical path where a light is channeled is formed due to reflection at the interface between the insulating film with a high refractive index and the insulating film with a low refractive index. According to this, reflection of incident light by the wiring is restrained, hence improving light-receiving efficiency of the PD. However, also on the PD, there is the same insulating film as the insulating film covering the wiring layer. Since a difference in the refractive index is large between the insulating film on the PD and the insulating film with a high refractive index forming the optical path, the incident light is reflected on the boundary surface and the PD does not receive the light efficiently.

### DESCRIPTION OF THE DRAWINGS

FIG. 1 is a cross-sectional view of a solid state imaging device according to a first embodiment.

FIGS. 2-11 are cross-sectional views illustrating the manufacturing process of the solid state imaging device according to the first embodiment.

### DETAILED DESCRIPTION

In general, according to one embodiment, there is provided a solid state imaging device with a high sensitivity to light—that is, the solid state imaging device may perform well in low light conditions (exposure to low intensity light).

According to one embodiment, a solid state imaging device includes: a semiconductor substrate; a photodiode formed in the semiconductor substrate; a first insulating film having a first refractive index, and disposed on a surface of the semiconductor substrate; a second insulating film having a second refractive index higher than the first refractive index, and formed on the first insulating film above the photodiode; a third insulating film having a third refractive index higher than the second refractive index, and formed on the second insulating film above the photodiode; and a micro lens provided above the photodiode.

### First Embodiment

Hereinafter, a solid state imaging device according to one embodiment is described with reference to the drawings.

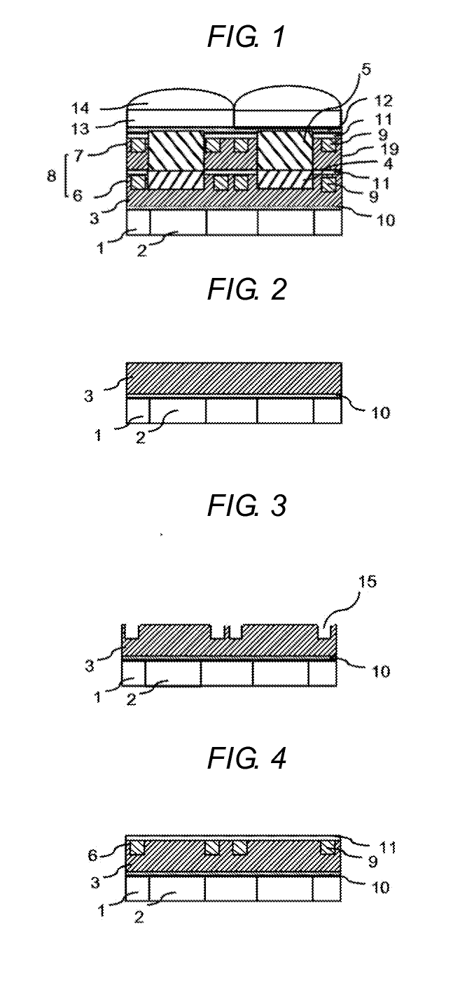

FIG. 1 is a cross-sectional view illustrating a part of the solid state imaging device according to the first embodiment. As illustrated in FIG. 1, the solid state imaging device includes a semiconductor substrate 1, a photodiode (PD) 2, a first insulating film 3, a second insulating film 4, a third insulating film 5, a first wiring layer 6, a second wiring layer 7(the first (6) and second (7) wiring layers may be collectively referred to as a multilayer wiring layer 8), a wiring 9, a first anti-reflection film 10, a protective film 11, a second anti-reflection film 12, a color filter 13, a micro lens 14, and a fourth insulating film 19. The solid state imaging device includes a micro lens on the PD, receives light, and converts light with the PD. In this context, a “wiring” is a metal/conductive component of a “wiring layer.” A “wiring layer” includes at least one “wiring” and the insulating material in which the “wiring” is embedded or surrounded.

The PD 2 is provided on the surface of the semiconductor substrate 1. The first insulating film 3 with a first refractive index is provided on the semiconductor substrate 1.

The second insulating film 4 is provided on the first insulating film 3 above the PD 2. The second insulating film 4 has a second refractive index higher than the first refractive index.

The third insulating film 5 is provided on the second insulating film 4 above the PD 2. The third insulating film 5 has a third refractive index higher than the second refractive index.

The above-mentioned second insulating film 4 is provided within the first insulating film 3 and surrounded by the first insulating film 3 in a direction parallel to the surface of the semiconductor substrate 1. Further, the third insulating film 5 is surrounded by the fourth insulating film 19. Here, the fourth insulating film 19 may be made of the same material as the first insulating film 3 or a different material. When the materials are different, the refractive index of the fourth insulating film 19 should be lower than the third refractive index.

A multilayer wiring layer 8 is formed within the first insulating film 3 and the fourth insulating film 19. The multilayer wiring layer can be provided between the second insulating films 4 (each film 4 being above an adjacent PD 2) and between the third insulating films 5 (each film 5 being above a respective film 4), in a direction parallel to the surface of the semiconductor substrate 1. The multilayer wiring layer provided within the first (3) and fourth (19) insulating films is formed by a plurality of wiring layers and includes the first wiring layer 6 and the second wiring layer 7. The first wiring layer 6 and the second wiring layer 7 are stacked each other in a direction perpendicular to the surface of the semiconductor substrate 1.

Each of the plurality of wiring layers includes a plurality of wirings 9 spaced from each other with the first (3) or fourth (19) insulating film interposed therebetween, and extending along a plane parallel to the semiconductor substrate 1 surface. The wirings 9 of the wiring layer can be electrically connected to the wirings 9 at different levels through a via (not illustrated), if necessary, in a direction perpendicular to the semiconductor substrate 1.

For example, Cu is used for the wiring 9 and the via. The color filter 13 is provided on the uppermost insulating film layer via the protective film 11 and the second anti-reflection film 12.

The multilayer wiring structure in this embodiment has a two-layered structure, for the sake of easy description, however, more than two wiring levels may be adopted in some embodiments.

Here, although only the insulating film up to the third insulating film 5 is illustrated, another insulating film or more may be provided above the PD 2 as long as each additional film in the stack has a higher refractive index in a direction perpendicular to the surface of the semiconductor substrate 1.

The second refractive index of the second insulating film 4 may increase gradually or in stages from the first insulating film 3 toward the third insulating film. 5. Alternatively, the second refractive index may be fixed (constant) at a predetermined value that is between the first refractive index and the third refractive index. In other words, the second insulating film. 4 has an intermediate refractive index between the first insulating film 3 (with the lowest refractive index in the stack) and the third insulating film 5 (with the highest refractive index in the stack). The third refractive index of the third insulating film 5 may increase in stages, similarly to the second refractive index of the second insulating film 4, or may be a fixed value.

On the uppermost portion of the insulating film layer, a micro lens 14 corresponding to one pixel is formed on the color filter 13 via the protective film 11 and the second anti-reflection film 12.

Hereinafter, the operation of the solid state imaging device is described.

The micro lens 14 focuses light incident on the solid state imaging device toward the PD 2.

The incident light passing through the micro lens 14 passes through the color filter 13.

The incident light passing through the color filter 13 enters the third insulating film 5 formed above the PD 2.

The third insulating film 5 is surrounded by the fourth insulating film 19 in a direction parallel to the surface of the semiconductor substrate 1. According to this, the third insulating film 5 forms an optical path toward the PD 2 in a direction perpendicular to the surface of the semiconductor substrate 1. Due to the difference between the refractive index of the fourth insulating film 19 and the third insulating film 6, the incident light efficiently propagates through the optical path in the perpendicular direction to the surface of the semiconductor substrate 1.

The first insulating film 3 is provided on the top surface of the PD 2 in order to avoid a malfunction of the PD 2 due to the process damage from forming the optical path and/or wiring layers. When the difference in the refractive index is great at the interface between the third insulating film 5 and the first insulating film 3 formed on the top surface of the PD 2, the incident light is reflected. Consequently, the PD 2 cannot receive the incident light efficiently.

However, in the solid state imaging device according to the embodiment, an insulating film (e.g., film 4) serves as an intermediate layer, with respect to the refractive index, between the first insulating film 3 and the third insulating film 5 in order to reduce the difference in the refractive index there.

The second insulating film 4 (having a refractive index higher than the first refractive index and lower than the third refractive index) is provided between the first insulating film 3 with the first refractive index and the third insulating film 5 with the third refractive index. As illustrated in FIG. 1, by providing the insulating film as the intermediate layer with respect to the refractive index, light-receiving efficiency in the PD 2 is improved.

The difference in the refractive index is smaller between the first insulating film 3 and the second insulating film 4 and between the second insulating film 4 and the third insulating film 5 than the difference between the first insulating film 3 and the third insulating film 5. Therefore, in the solid state imaging device according to the embodiment, the PD 2 efficiently receives light.

Next, a method of manufacturing a solid state imaging device is described with reference to the drawings.

In an initial step, dopant ions are injected into the semiconductor substrate 1, for example, made of Si, to form the PD 2.

As illustrated in FIG. 2, for example, SiN is formed on the whole semiconductor substrate 1 to cover the plurality of PD 2 previously formed on the substrate. This covering layer is the first anti-reflection film 10, for example, and may be deposited according to the plasma Chemical Vapor Deposition (CVD) method.

For example, SiO₂ is formed on the whole first anti-reflection film 10 to be the first insulating film 3 with the first refractive index, for example, according to the plasma CVD or thermal CVD method.

Next, as illustrated in FIG. 3, a groove 15 is formed in the first insulating film. 3, for example, using lithography and a dry etching technique, in order to form the wiring within the first insulating film 3.

Next, although it is not specifically illustrated, a barrier metal such as tantalum (Ta), tantalum nitride (TaN), titanium (Ti) or titanium nitride (TiN) is formed as a film on the surface of the groove 15, for example, using a sputtering method, in order to prevent diffusion of the Cu used for the wiring 9 into the insulating film.

As illustrated in FIG. 4, after the barrier metal is formed, Cu for the wiring 9 is embedded into the groove 15 by plating. The surface of Cu and the first insulating film 3 are flattened according to the Chemical Mechanical Polishing (CMP) method. Thus, the wiring 9 made of Cu is formed inside (embedded in) the first insulating film 3. Then, the protective film 11 made of, for example, SiN is formed on the first insulating film 3 and the Cu wiring 9, according to the plasma CVD method to prevent diffusion of the Cu wiring 9 of the first wiring layer 6 into the forth insulating film 19 which is formed on the Cu wiring 9 and the first insulating film 3 later (or subsequent insulation film layers).

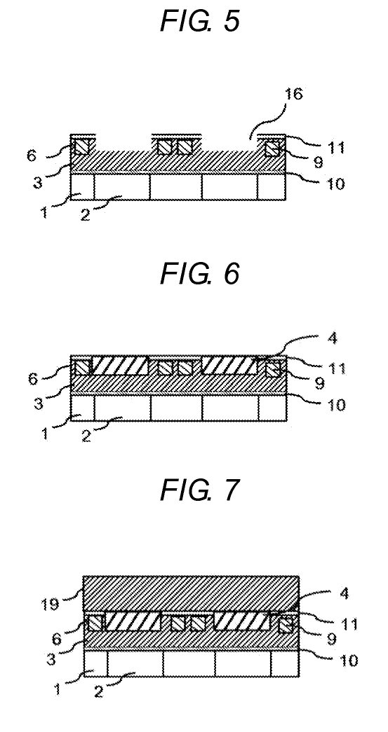

Then, the second insulating film 4 is formed within the same layer as the first wiring layer 6. As illustrated in FIG. 5, after the first wiring layer 6 is formed, a groove 16 is formed above the PD 2 within the first insulating film 3, for example, according to the Reactive Ion Etching (RIE) and/or wet etching method. Here, the groove 16 does not reach the first anti-reflection film 10.

As illustrated in FIG. 6, the second insulating film 4 is formed on the groove 16 according to the plasma CVD method. Then, the second insulating film 4 is flattened, for example, according to the CMP or RIE method. Thus, the second insulating film 4 is formed above the PD 2 within the first insulating film 3. The first wiring layer 6 and the second insulating film 4 are formed within the same layer.

Subsequently, a second wiring is formed. As illustrated in FIG. 7, the fourth insulating film 19 is formed on the protective film 11 (similarly to the formation of first insulating film 3 as in FIG. 2) according to the plasma CVD method.

The fourth insulating film 19 may be made of the same material as the first insulating film 3 or a different material . When the material is different, the refractive index of the film 19 should be lower than the second refractive index and the third refractive index.

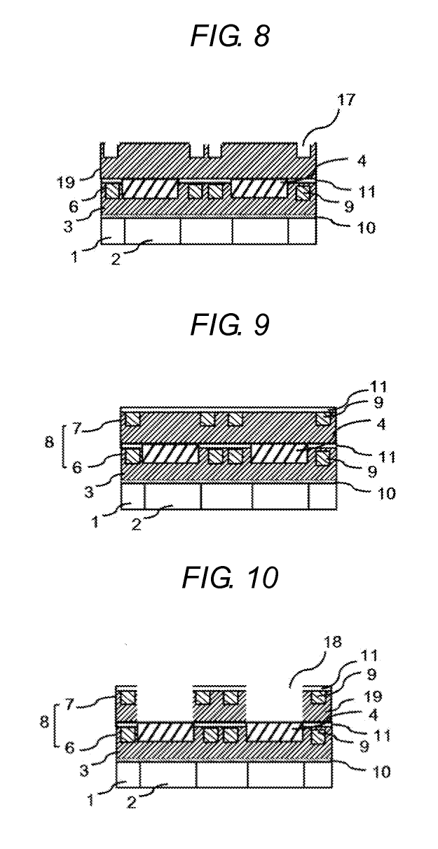

Next, as illustrated in FIG. 8, similarly to FIG. 3, a groove 17 is formed on the surface of the fourth insulating film 19, for example, according to the lithography and dry etching technique (e.g., reactive ion etching).

Although it is not specifically illustrated, a barrier metal is formed on the surface of the groove 17, for example, according to the sputtering method, to prevent diffusion of the Cu used for the wiring 9 into the insulating films.

After the barrier metal is formed, as illustrated in FIG. 9, Cu used for the wiring 9 is embedded into the groove 17 by plating. The surface of Cu and the fourth insulating film 19 is flattened according to the CMP method. Thus, the wiring 9 made of Cu is formed on the fourth insulating film 19. Next, another protective film 11 made of SiN is formed according to the plasma CVD method in order to prevent diffusion of Cu from the wiring 9 into the subsequent insulating film (e.g. protective film 11 or the second anti-reflection film 12).

Next, the third insulating film 5 is formed. After the second wiring layer 7 is formed, as illustrated in FIG. 10, a groove 18 extending from the surface of the fourth insulating film 19 to the top surface of the second insulating film 4 is formed in the fourth insulating film 19 above the PD 2 according to the RIE and/or wet etching method. In this embodiment, as depicted in FIG. 10, the groove 18 penetrates substantially the full thickness of the fourth insulating film 19.

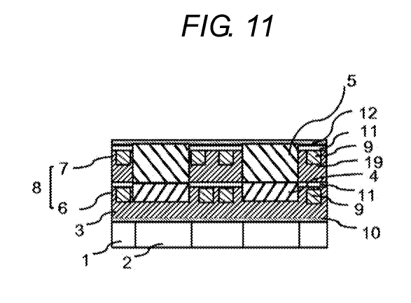

As illustrated in FIG. 11, the third insulating film 5 is formed in the groove 18 according to the plasma CVD method or the like, and then, the third insulating film 5 is flattened, for example, according to the CMP or RIE method. According to this embodiment, the third insulating film 5 is formed above the PD 2 in the fourth insulating film 19 in direct contact with the second insulating film 4. Next, a second anti-reflection film 12 made of, for example, SiN is formed on the top surface of the third insulating film 5 and the protective film 11 according to the plasma CVD or sputtering method. On the top surface of the second anti-reflection film 12, the micro lens 14 is formed via the color filter 13 correspondingly to each of PDs 2. As mentioned above, the solid state imaging device illustrated in FIG. 1 is completed.

The first insulating film 3 and the fourth insulating film 19 are made of, for example, silicon oxide (refractive index is 1.4). The second insulating film 4 and the third insulating film 5 are made of, for example, silicon nitride having various nitrogen compositions and the refractive indexes thereof. The refractive indexes of the second insulating film 4 and the third insulating film 5 are, for example, 1.6 and 2.0 respectively.

Although the example first embodiment has been made with silicon nitride of various compositions and silicon oxide as the first insulating film 3, the second insulating film 4, the third insulating film 5, and the fourth insulating film 19, the material is not restricted to these, by adding, for example, Ti to the insulating material, the refractive index of the insulating material can be varied.

Further, although the description has been made with the plasma CVD method used for a method for forming an insulating film, the method is not restricted to the plasma CVD method; the film can be formed by using the sputtering method or other application methods.

While certain embodiments have been described, these embodiments have been presented by way of example only, and are not intended to limit the scope of the inventions . Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device, comprising:
a photodiode;
a first insulating film disposed on a surface of the photodiode and having a first refractive index;
a second insulating film having a second refractive index higher than the first refractive index and disposed on the first insulating film above the photodiode, the first insulating film being between the second insulating film and the photodiode in a first direction orthogonal to the surface of the photodiode;
a third insulating film disposed on the second insulating film above the photodiode and having a third refractive index higher than the second refractive index, the second insulating film being between the third insulating film and the photodiode in the first direction; and
a micro lens disposed on the photodiode.

2. The device according to claim 1, wherein a fourth insulating film having a fourth refractive index smaller than the third refractive index is disposed on lateral sides of the second and the third insulating films.

3. The device according to claim 2, wherein the fourth refractive index is equal to the first refractive index.

4. The device according to claim 1, wherein wiring is provided within the first insulating film and spaced in a second direction parallel to the surface of the photodiode from the second insulating film.

5. The device according to claim 1, wherein the second refractive index of the second insulating layer increases with distance from the surface of the photodiode in the first direction.

6. The device according to claim 5, wherein the second refractive index increases gradually with distance from the surface of the photodiode in the first direction.

7. The device according to claim 1, wherein the first insulating film has a refractive index of about 1.4.

8. The device according to claim 1, wherein the second insulating film has a refractive index of about 1.6.

9. The device according to claim 1, wherein the third insulating film has a refractive index of about 2.0.

10. An electronic device, comprising:
a photodiode;
a first insulating material having a first refractive index and disposed on the photodiode;
a second insulating material having a second refractive index and embedded in the first insulating material such that the first insulating material is between the second insulating material and the photodiode, the second refractive index being higher than the first refractive index;
a third insulating material having a third refractive index and disposed on the second insulating material such that the second insulating material is between the third insulating material and the photodiode, the third refractive index being higher than the second refractive index;
a fourth insulating material having a fourth refractive index and disposed on the first insulating material and lateral surfaces of the third insulating material, the fourth refractive index being lower than the third refractive index; and
a plurality of wires disposed in the first and fourth insulating materials.

11. The electronic device according to claim 10, further comprising:
a color filter on the fourth and third insulating materials; and
a micro lens on the color filter.

12. The electronic device according to claim 10, wherein the first insulating material comprises silicon dioxide and the second and third insulating materials comprise silicon and nitrogen.

13. The electronic device according to claim 10, wherein the second refractive index increases with distance from the photodiode.

14. A method of fabricating a solid state imaging device, the method comprising:
forming a first insulating film having a first refractive index on a substrate including a photodiode;
forming a first groove in the first insulating film and embedding a conductive material in the first groove;
forming a second groove in the first insulating film, the second groove being above and aligned to the photodiode;
forming a second insulating film having a second refractive index in the second groove, the second refractive index being higher than the first refractive index;
forming a fourth insulating film on the first and second insulating films;
forming a third groove in the fourth insulating film and embedding a conductive material in the third groove;
forming a fourth groove in the fourth insulating film, the fourth groove being above and aligned to the photodiode; and
forming a third insulating film having a third refractive index in the fourth groove, the third refractive index being greater than the second refractive index

15. The method of claim 14, further comprising:
forming a color filter above the photodiode.

16. The method of claim 15, further comprising:
forming a micro lens on the color filter.

17. The method of claim 14, further comprising:
forming a micro lens above the photodiode.

18. The method of claim 14, wherein the third refractive index is about 2.0, the second refractive index is about 1.6, and the first refractive index is about 1.4.

19. The method of claim 14, wherein the second refractive index of the second insulating film increases with distance from the photodiode.

20. The method of claim 19, wherein the second insulating film comprises silicon nitride and titanium.
